(19) United States
(12) Patent Application Publication
(10) Pub. No.: US 2025/0029857 A1
(43) Pub. Date: Jan. 23, 2025

(54) MODULE RETAINER

(71) Applicant: ENTEGRIS, INC., Billerica, MA (US)

(72) Inventors: Mark V. Smith, Colorado Springs, CO (US); Shawn D. Eggum, Lonsdale, MN (US); Matthew A. Fuller, Colorado Springs, CO (US)

(21) Appl. No.: 18/778,862

(22) Filed: Jul. 19, 2024

Related U.S. Application Data
(63) Continuation-in-part of application No. 18/648,149, filed on Apr. 26, 2024.
(60) Provisional application No. 63/528,292, filed on Jul. 21, 2023.

(51) Int. Cl. H01L 21/673

(52) U.S. Cl. CPC H01L 21/67393; H01L 21/67379; H01L 21/67386

(57) ABSTRACT

A module retainer is provided that can be rotatably attached to a purge module. The module retainer includes one or more engagement features configured to be inserted through openings provided in a substrate container and to engage tabs when rotated following insertion through the openings. The module retainer can be rotatable with respect to the purge module such that rotation between the insertion position and the retention position can be performed without affecting an orientation of the purge module.

### FIELD

This disclosure is directed to retainers for installation of purge modules and purge modules and substrate containers including such retainers.

### BACKGROUND

Purge assemblies for substrate containers such as front-opening uniform pods (FOUPs) typically include multiple discrete components including a grommet, a filter, a valve, and various sealing members.

### SUMMARY

This disclosure is directed to retainers for installation of purge modules and purge modules and substrate containers including such retainers.

By providing a retainer that can be attached to a purge module, installation of purge modules into substrate container and/or removal of such modules (for servicing, replacement, etc.) can be simplified and the attachment of the purge module to the substrate container made more secure. By being freely rotatable relative to the purge module, the retainer can be manipulated to engage or disengage from the substrate container without otherwise affecting the orientation of the purge module it is attached to. The retainer can further include one or more tooling interfaces, allowing the use of automation to operate the retainer so as to secure the purge module to the substrate container.

In an embodiment, an assembly includes a substrate container. The substrate container includes an aperture formed in the substrate container. The aperture is configured to receive a module. The substrate container further includes one or more tabs, each of the one or more tabs extending inwards into the aperture over a portion of a perimeter of the aperture, the one or more tabs defining one or more gaps. The assembly further includes a module and a module retainer attached to the module. The module retainer includes one or more of engagement features, and the engagement features are configured to be inserted through a corresponding one or more of gaps when in a first position and to engage with the one or more tabs when in a second position. The module retainer is configured to be rotatable between the first position and the second position when the module retainer is inserted into the aperture.

In an embodiment, the module retainer includes a detent configured to contact one of the one or more gaps so as to resist rotation of the module retainer from the second position to the first position.

In an embodiment, the module is selected from the group consisting of: a vent module, a purge module, a getter module, a sensor module, and an interface module.

In an embodiment, the one or more tabs include at least three tabs, and the one or more engagement features includes at least three engagement features.

In an embodiment, the substrate container includes a shell defining an internal space and a bottom plate. In an embodiment, the aperture is formed in the shell. In an embodiment, the aperture is formed in both the shell and the bottom plate. In an embodiment, the one or more tabs are provided on the bottom plate.

In an embodiment, the module retainer includes one or more tooling interfaces on an outward-facing surface of the module retainer. In an embodiment, the tooling interfaces are distributed around a central opening formed in the outward-facing surface of the module retainer.

In an embodiment, a method of installing a module into a substrate container includes inserting a module including a module retainer into an aperture formed in the substrate container, wherein the module retainer is in a first position where engagement features of the module retainer can pass through gaps between tabs extending inwards into the aperture and rotating the module retainer into a second position where the engagement features of the module retainer engage with the tabs.

In an embodiment, the method further includes attaching the module retainer to the module. In an embodiment, attaching the module retainer to the module includes forming a snap-fit between at least one first snap-fit feature provided on the module retainer and at least one second snap-fit feature provided on a body of the module.

In an embodiment, the aperture is formed in a shell of the substrate container.

In an embodiment, the aperture is formed in a shell and a bottom plate of the substrate container, and the tabs are provided on the bottom plate.

In an embodiment, rotating the module retainer includes inserting a tool into one or more tooling interfaces provided in the module retainer. In an embodiment, the tool is manipulated by automation.

In an embodiment, the method further includes rotating the module retainer from the second position to the first position and removing the module from the aperture.

In an embodiment, when the module is installed in the aperture and the module retainer is in the second position, the aperture is sealed.

### DRAWINGS

FIG. 1 shows a perspective view of a module retainer according to an embodiment.

FIG. 2 shows a sectional view of a purge module including a module retainer according to an embodiment.

FIG. 3 shows an exploded view of a substrate container according to an embodiment.

FIG. 4 shows a bottom plate and a module retainer according to an embodiment.

FIG. 5 shows a sectional view of a bottom plate and a module retainer according to an embodiment.

FIG. 6 is a flowchart of a method for installing a purge module into a substrate container according to an embodiment.

FIG. 7 shows a perspective view of a getter module including a module retainer according to an embodiment.

FIG. 8 shows a perspective view of a sensor module including a module retainer according to an embodiment.

FIG. 9 shows a perspective view of a vent module including a module retainer according to an embodiment.

### DETAILED DESCRIPTION

This disclosure is directed to retainers for installation of purge modules and purge modules and substrate containers including such retainers.

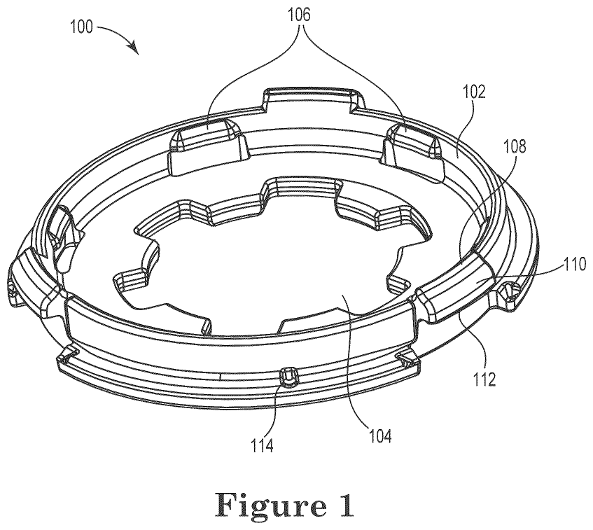

FIG. 1 shows a perspective view of a module retainer according to an embodiment. Module retainer 100 includes retainer body 102 defining an opening 104. A module attachment feature 106 can be provided on an inner surface of retainer body 102. The module retainer further includes one or more retention engagement features 108.

Module retainer 100 is configured to allow a module to be secured to a substrate container. The module can be any suitable module, with non-limiting examples of modules including purge modules, getters, sensor modules, vent modules, or interface modules. The module retainer 100 includes a retainer body 102 defining opening 104. Opening 104 can be configured such that a device external to the substrate container can interface with the module, for example allowing a purge module to interface with a purge gas supply port or line, or any other such suitable interface with a module. The retainer body 102 defines an inner surface configured such that the inner surface can surround a portion of the module. The inner surface includes one or more module attachment features 106. Module attachment features 106 are one or more features allowing a mechanical attachment of the module retainer 100 to the module. The module attachment feature 106 can be configured such that the module retainer 100 can be rotated relative to the module when the module retainer 100 is attached to said module. In an embodiment, the rotation permitted by the attachment of module retainer 100 to the module can be free rotation between a first alignment and a second alignment. In an embodiment, the rotation permitted by the attachment of module retainer 100 to the module can be free rotation through a full 360 degrees. In an embodiment, the mechanical attachment provided by module attachment feature 106 and corresponding suitable features on the module can be a snap-fit. In an embodiment, the module attachment feature 106 can be an annular projection configured to form a snap-fit with features provided on the module. In embodiments, a plurality of module attachment features 106, for example a plurality of snap-fit features separated by gaps formed therebetween as shown in FIG. 1.

Module retainer 100 further includes one or more retention engagement features 108. The retention engagement features 108 are configured to include an insertion portion 110 that is configured to be insertable through a corresponding feature provided on a substrate container used with the module retainer 100. The insertion portion 110 includes a retention contact surface 112. The retention contact surface 112 is configured to contact the feature provided on the substrate container once the insertion portion 110 has been inserted into the feature and the module retainer 100 rotated into a retention position. The feature on the substrate container receiving the insertion portion 110 can include one or more tabs defining one or more openings configured such that the insertion portion 110 can be inserted through a corresponding opening when the module retainer 100 is in an insertion orientation, and when the module retainer 100 is rotated into a retention orientation, the retention contact surface 112 contacts the tab.

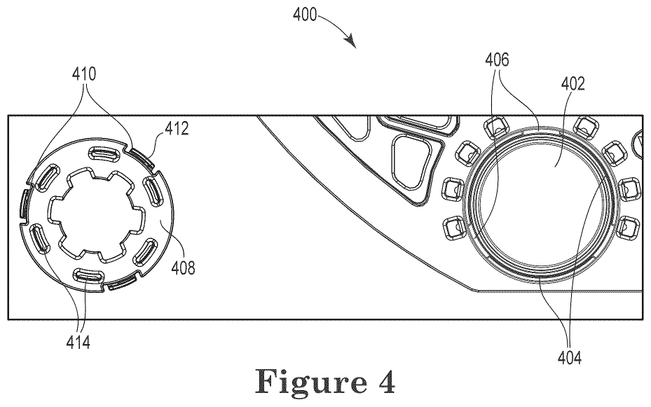

In an embodiment, a detent 114 can be provided on the retainer body 102. The detent 114 can be configured to prevent the retainer module from backing out of the substrate container when the module retainer 100 is attached to the substrate container. The detent can be positioned, sized, and shaped to contact an edge of a gap between tabs provided on the substrate container, such as gaps 406 provided between tabs 404 shown in FIG. 4 and described below, when the module retainer 100 is in a retaining position. The detent can resist rotation of the module retainer 100 from the retaining position back to an insertion or removal position of the module retainer 100 relative to the substrate container.

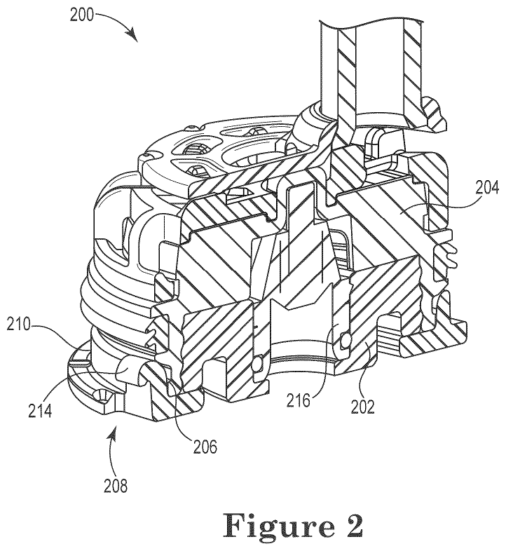

FIG. 2 shows a sectional view of a purge module including a module retainer according to an embodiment. Purge module 200 includes grommet 202 and module body 204. Module body 204 includes retainer attachment feature 206. Module retainer 208 is shown as being attached to module body 204. Module retainer 208 includes retainer body 210, including retention engagement features 214.

Purge module 200 is a module configured to receive a flow of purge gas to be directed into the substrate container to which the purge module 200 is attached. The purge module 200 includes grommet 202. The grommet 202 can include an aperture configured to receive a flow of purge gas from a purge gas source, such as a port provided on a tool where the substrate container including purge module 200 is to be used. The grommet 202 can further include a portion configured to receive a check valve such that check valve can receive the purge gas introduced at the aperture of grommet 202.

Purge module 200 further includes module body 204. Module body 204 is configured to receive the grommet 202 and check valve 216. The module body can include any suitable features for use or operation of the purge module, such as features for retaining a filter, allowing attachment of a diffusion device, and the like. A retainer attachment feature 206 is provided on the module body 204. The retainer attachment feature 206 is a feature configured to allow the attachment of module retainer 208 to the purge module 200. The retainer attachment feature 206 can be any suitable feature to allow a rotatable mechanical attachment of the module retainer 208 to purge module 200. As non-limiting examples, the retainer attachment feature 206 can be an annular groove configured to receive a snap-fit feature provided as the module attachment feature on module retainer 208. The module attachment feature provided on module retainer 208 can be, for example, module attachment features 106 shown in FIG. 1 and described above.

Module retainer 208 is a retainer configured to join the purge module 200 to a substrate container. Module retainer 208 includes retainer body 210 having an inner surface configured to surround a portion of the purge module 200. A module attachment feature, such as module attachment features 106 shown in FIG. 1 and discussed above can be provided on the inner surface of retainer body 210. The module attachment feature can be any suitable attachment feature for engaging with retainer attachment feature 206 of purge module 200, such that module retainer 208 can be rotated relative to the purge module 200. For example, when retainer attachment feature 206 is an annular groove, the module attachment feature can be an annular projection configured to be snap-fit into the annular groove. In embodiments, a plurality of the module attachment features can be provided on the module retainer 208, for example a plurality of projections disposed about the inner surface and configured to engage with the retainer attachment feature 206 of purge module 200.

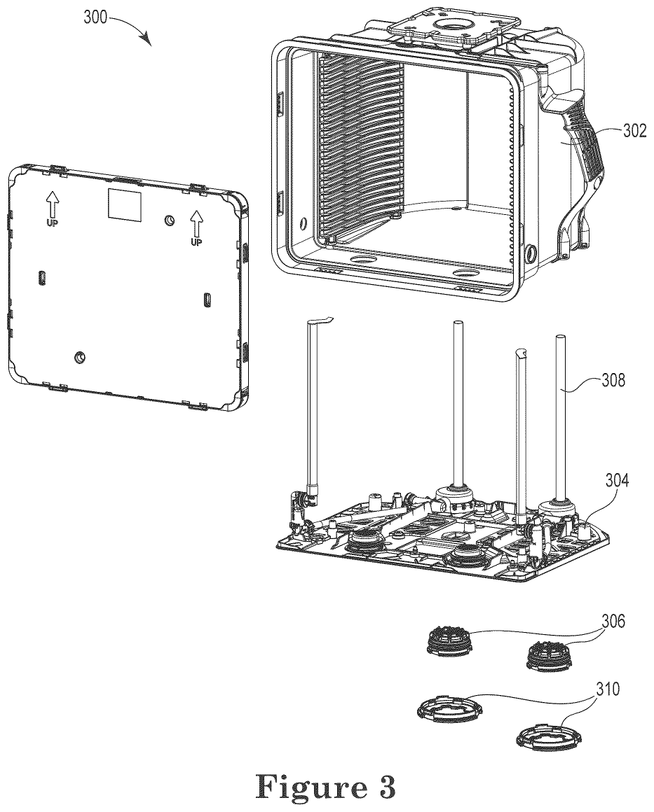

FIG. 3 shows an exploded view of a substrate container according to an embodiment. Substrate container 300 includes shell 302, bottom plate 304, purge module 306, diffusion device 308, and module retainer 310.

Substrate container 300 is a configured to contain substrates, such as semiconductor wafers or any other suitable substrates, during transportation, storage, and/or processing of those substrates. Substrate container 300 includes shell 302, which can define an internal space capable of accommodating one or more substrates. The shell 302 can define the internal space by way of top, bottom, side, and back walls with an open front side provided to allow the insertion or removal of the substrates from the internal space. Bottom plate 304 can be included in substrate container 300. Bottom plate 304 can be configured to facilitate handling of the substrate container, include interfaces for receiving and retaining purge modules 306 and/or diffusion devices 308, or the like. In an embodiment, bottom plate 304 is a conveyor plate of the substrate container 300.

Purge module 306 can be configured to interface with a source of purge gas, such as a purge gas line of a tool that substrate container 300 is configured to be used with. In an embodiment, purge module 306 includes a diffusion device 308. In an embodiment, a diffusion device 308 can be attached to the purge module 306. In an embodiment, the diffusion device 308 can be configured to be retained in part within shell 302 by features provided on one or more of the purge module 306, bottom plate 304, and shell 302. Purge module 306 is configured such that module retainer 310 can be rotatably attached to the purge module 306, such that when the module retainer 310 is attached to the purge module 306, the module retainer can be rotated 310 without causing rotation or otherwise affecting an orientation of the purge module 306.

Diffusion device 308 is configured to allow diffusion of gas, such as a purge gas, into the internal space defined by shell 302. In an embodiment, the gas provided by diffusion devices 308 can be used to purge the internal space defined by shell 302, for example to remove contaminants including but not limited to moisture, volatile organic compounds (VOCs) and the like. The gas can be, as non-limiting examples, nitrogen, an inert gas, clean dry air (CDA), extra clean dry air (xCDA), or the like. Diffusion devices 308 can be, for example, diffuser towers. Diffusion devices 308 can be made of a porous material to allow the diffusion of the gas through the diffusion devices 308. The diffusion devices 308 can receive the gas to be provided to the internal space by way of purge module 306.

Module retainer 310 is a module retainer, such as either of module retainers 100 or 208 as described above and shown in FIGS. 1 and 2. Module retainer 310 is configured to be attached to the purge module 306. Module retainer 310 is further configured to engage with the substrate container 300, for example at bottom plate 304 and/or shell 302, such that the purge module 306 can be retained in substrate container 300.

FIG. 4 shows a bottom plate and a module retainer according to an embodiment. Bottom plate 400 defines aperture 402. One or more tabs 404 are provided around aperture 402. The one or more tabs define corresponding one or more gaps 406. The module retainer 408 includes one or more projections 410 including retention engagement features 412.

Bottom plate 400 is a bottom plate of a substrate container. The bottom plate 400 defines aperture 402. While FIG. 4 shows a bottom plate 400 including the aperture 402 and one or more tabs 404 defining one or more gaps 406, the aperture 402, tabs 404, and gaps 406 can be provided on another part of a suitable substrate container, for example on a shell of the substrate container such as shell 302 described above and shown in FIG. 3. The aperture 402 can allow passage of a module, such as a purge module, into the substrate container. The module can be passed through aperture 402 into any suitable part of the substrate container, such as the interior space defined by the shell of the container, a chamber configured to receive purge gas, or the like. One or more tabs 404 can project into aperture 402. The one or more tabs define at least one gap 406. The gap 406 is sized such that one of the one or more projections 410 can be passed through the gap 406 when said projection 410 is aligned with the gap 406.

Module retainer 408 is a module retainer such as module retainers 100, 208, or 310 as discussed above and shown in FIGS. 1-3. Module retainer 408 includes one or more projections 410. The projections 410 can be sized such that each of projections 410 can pass through a corresponding one of gaps 406 provided on bottom plate 400. The projections 410 can include a first portion that is within aperture 402 when the module retainer 408 is inserted, and a second portion that would interfere with the tabs 404 unless aligned with the gaps 406. In an embodiment, a plurality of projections 410 are provided on module retainer 408. In an embodiment, the plurality of projections can be radially distributed about a perimeter of the module retainer 408. Each of the one or more projections 410 includes a retention engagement feature 412 provided on the second portion thereof. The retention engagement features 412 can be, for example, contact surfaces configured to engage with the tabs 404 when the module retainer 408 is rotated from the position where projections 410 passing through the gaps 406 to a retention position. The module retainer 408 further includes tooling interfaces 414. The tooling interfaces 414 can be any suitable features allowing module retainer 408 to be engaged by one or more features provided on a tool such that the tool can be used to rotate the module retainer 408. Non-limiting examples of tooling interfaces 414 include one or more projections or recesses provided in the surface of the module retainer 408. In an embodiment, a plurality of the tooling interfaces 414 can be distributed radially about the module retainer 408.

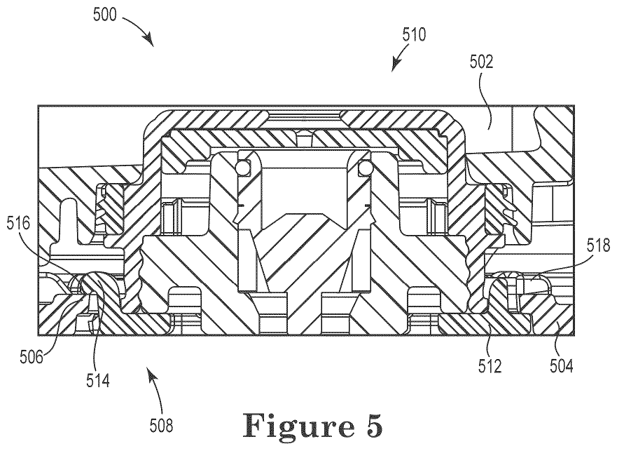

FIG. 5 shows a sectional view of a substrate container and a module retainer according to an embodiment. Substrate container 500 includes shell 502 and bottom plate 504. The bottom plate 504 includes one or more tabs 506, extending into aperture 508 defined in bottom plate 504. The aperture 508 is configured to receive module 510. The module 510 is attached to a module retainer 512. The module retainer 512 includes one or more projections 514, with each of the one or more projections 514 including a retention feature 516. The bottom plate 504 can further include one or more stops 518.

Substrate container 500 includes shell 502 defining an internal space where one or more substrates can be accommodated. Substrate container 500 can include bottom plate 504. Bottom plate 504 can be, for example, a conveyor plate of the substrate container 500. One or more tabs 506 are provided around a perimeter of aperture 508 defined in the bottom plate 504. In an alternate embodiment, the aperture 508, tabs 506, and stops 518 can be formed in shell 502 instead of bottom plate 504.

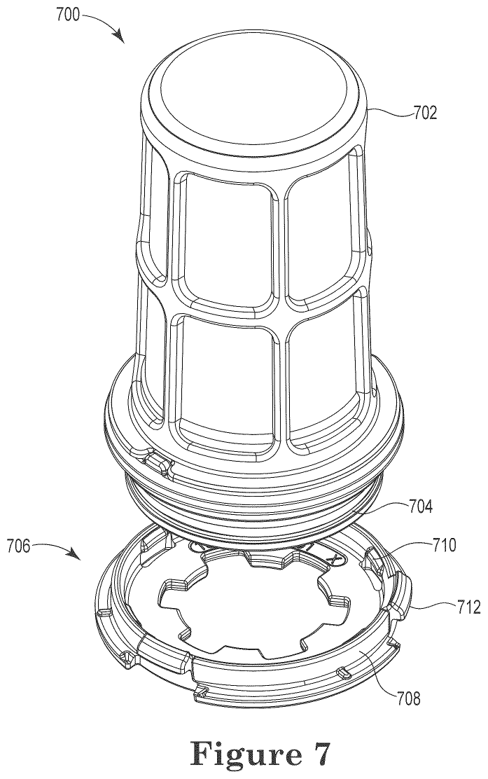

Module 510 can be any suitable module, such as, for example, a purge module as shown in FIG. 5, or a getter module, a sensor module, a vent module, or an interface module such as those described below and shown in FIGS. 7-10. The module 510 is attached to module retainer 512, for example through a snap-fit using suitable features. The module retainer 512 includes one or more projections 514 each including a retention feature 516 configured to engage with a corresponding one or more of the tabs 506 when the module retainer 512 is rotated into a retention position when module 510 is inserted into aperture 508.

Stops 518 can be provided within aperture 508. The stops 518 are shaped and positioned such that the stops 518 can interfere with the travel of projections 514 when the module is inserted into the aperture and the module retainer is rotated. The stops 518 can be shaped and positioned to stop the rotation of the module retainer 512 when the module retainer 512 is in a position where module 510 will be retained within aperture 508 by contact of the retention features 516 with the tabs 506.

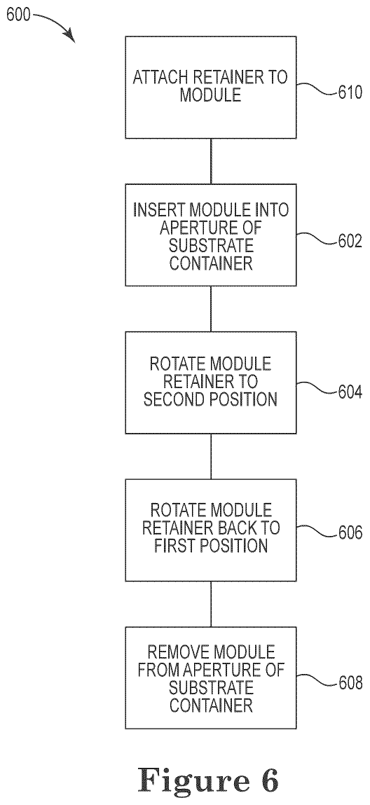

FIG. 6 is a flowchart of a method for installing a module into a substrate container according to an embodiment. Method 600 includes inserting a module including the module retainer into an aperture of the substrate container with the module retainer in a first position 602 and rotating the module retainer from the first position into a second position at 604. Optionally, the method 600 can further include rotating the module retainer from the second position to the first position at 606 and removing the module at 608. In an embodiment, the method 600 can further optionally include attaching the module retainer to the module at 610.

The module is inserted into the aperture with the module retainer in a first position at 602. The first position of the module retainer is a position where the projections, such as projections 410 described above and shown in FIG. 4, are aligned such that the projections can be received in gaps between tabs surrounding the aperture, such as the gaps 406 defined between tabs 404 described above and shown in FIG. 4.

The module retainer is rotated from the first position to a second position at 604. The second position is a position where the module retainer engages with the substrate container such that the module is retained to the substrate container. For example, in the second position, retention engagement features such as the retention engagement features 412 can be in contact with tabs provided around the aperture such as tabs 404, as described above and shown in FIG. 4. The rotation of the module retainer can be performed without causing rotation of the module that the module retainer is attached to. The rotation from the first position to the second position at 604 can, as non-limiting examples, be performed manually, using a tool, or by a tool operated by automation. In an embodiment, the substrate container can include stops, such as stops 518 as described above and shown in FIG. 5, to stop the rotation of the module retainer when the module retainer reaches the second position. In an embodiment, when the module retainer is rotated from the first position to a second position, a detent provided on the module retainer, such as detent 114 described above and shown in Figure I can be positioned within one of the gaps, such that contact of said detent with an edge of the of the gap can resist rotation of the module retainer back towards the first position. The retention provided by the detent can be such that the resistance to rotation can be overcome by rotational force applied by a user or tool.

FIG. 7 shows a perspective view of a getter module including a module retainer according to an embodiment. Getter module 700 includes getter module body 702 including retainer attachment feature 704. Module retainer 706 includes retainer body 708, module attachment feature 710, and retention engagement features 712.

Getter module 700 is a module configured to accommodate a getter material, for example to absorb materials such as contaminants from within a substrate container. Getter module 700 includes a getter module body 702. The getter module body 702 can include any suitable features for accommodating the getter material and allowing the getter material to absorb materials from within the substrate container. The getter material can be a material selected to absorb one or more known compounds, such as, for example, one or more acids, one or more bases, one or more volatile organic compounds, combinations thereof, or the like. The getter module body 702 further includes retainer attachment feature 704, which can be any suitable feature for interfacing with retention engagement features 712 of the module retainer 706 such that the module retainer 706 can be rotatably attached to getter module body 702. In an embodiment, the getter module body 702 can be the relatively tall getter module configured to extend into the interior space of the substrate container as shown in FIG. 7. In an embodiment, the getter module body 702 can instead be shaped such that it does not extend above a bottom inner wall of the substrate container.

Module retainer 706 is a retainer, such as any of module retainers 100, 208, 310, 408, or 510 as described above and shown in FIGS. 1-5. Module retainer 706 includes retainer body 708. Module attachment feature 710 can be provided on the inner surface of retainer body 708. The module attachment feature can be any suitable one or more attachment features for engaging with retainer attachment feature 704, such that module retainer 706 can be rotatably attached to getter module 700.

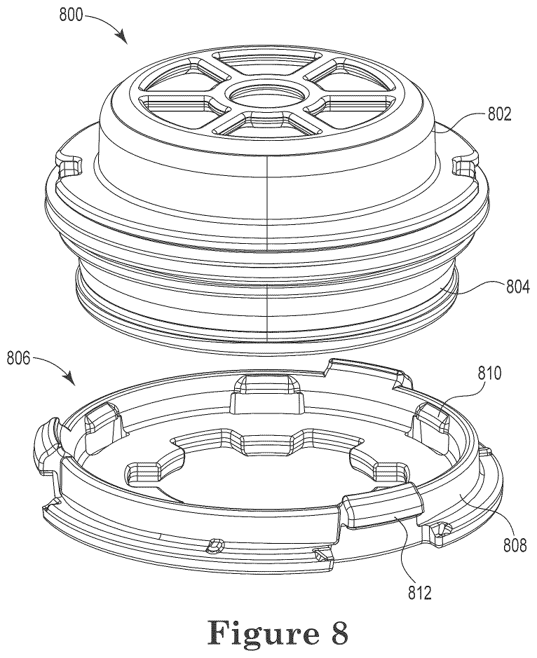

FIG. 8 shows a perspective view of a sensor module including a module retainer according to an embodiment. Sensor module 800 includes sensor module body 802 including retainer attachment feature 804. Module retainer 806 includes retainer body 808, module attachment feature 810, and retention engagement features 812.

Sensor module 800 is a module configured to accommodate a sensor, such that the sensor is provided within a substrate container. Sensor module 800 includes a sensor module body 802. The sensor module body 802 can include any suitable features for accommodating and presenting the sensor. The sensor module body 802 further includes retainer attachment feature 804, which can be any suitable feature for interfacing with retention engagement features 812 of the module retainer 806 such that the module retainer 806 can be rotatably attached to sensor module body 802.

Module retainer 806 is a retainer, such as any of module retainers 100, 208, 310, 408, or 510 as described above and shown in FIGS. 1-5. Module retainer 806 includes retainer body 808. Module attachment feature 810 can be provided on the inner surface of retainer body 808. The module attachment feature can be any suitable attachment feature for engaging with retainer attachment feature 804, such that module retainer 806 can be rotatably attached to sensor module 800.

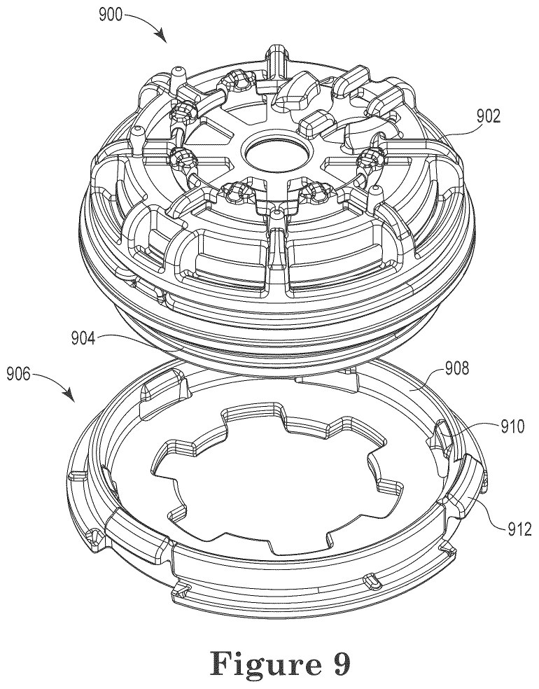

FIG. 9 shows a perspective view of a vent module including a module retainer according to an embodiment. Vent module 900 includes vent module body 902 including retainer attachment feature 904. Module retainer 906 includes retainer body 908, module attachment feature 910, and retention engagement features 912.

Vent module 900 is a module configured to allow venting of the substrate container into which vent module 900 is installed. Vent module 900 can include any suitable features for the venting of the substrate container. In an embodiment, vent module 900 can have contents similar to those of a purge module such as purge module 200 or 306 as described above and shown in FIGS. 2 and 3, except omitting a check valve. In an embodiment, the vent module 900 includes a breather filter as a filter included in the vent module 900. Vent module 900 includes a vent module body 902. The vent module body 902 includes retainer attachment feature 904, which can be any suitable feature for interfacing with retention engagement features 912 of the module retainer 906 such that the module retainer 906 can be rotatably attached to vent module body 902.

Module retainer 906 is a retainer, such as any of module retainers 100, 208, 310, 408, or 510 as described above and shown in FIGS. 1-5. Module retainer 906 includes retainer body 908. Module attachment feature 910 can be provided on the inner surface of retainer body 908. The module attachment feature can be any suitable attachment feature for engaging with retainer attachment feature 904, such that module retainer 906 can be rotatably attached to vent module 900.

### Aspects:

It is understood that any of aspects 1-10 can be combined with any of aspects 11-20.

Aspect 1. An assembly comprising a substrate container, the substrate container including:
an aperture formed in the substrate container, the aperture configured to receive a module;
one or more tabs, each of the one or more tabs extending inwards into the aperture over a
portion of a perimeter of the aperture, the one or more tabs defining one or more gaps;
a module; and a module retainer attached to the module, the module retainer including one or more of engagement features, wherein the engagement features are configured to be inserted through a corresponding one or more of gaps when in a first position and to engage with the one or more tabs when in a second position, the module retainer configured to be rotatable between the first position and the second position when the module retainer is inserted into the aperture.

Aspect 2. The assembly according to aspect 1, wherein the module retainer includes a detent configured to contact one of the one or more gaps so as to resist rotation of the module retainer from the second position to the first position.

Aspect 3. The assembly according to any of aspects 1-2, wherein the module is selected from the group consisting of: a purge module, a vent purge module, a getter module, and a sensor module.

Aspect 4. The assembly according to any of aspects 1-3, wherein the one or more tabs include at least three tabs, and the one or more engagement features includes at least three engagement features.

Aspect 5. The assembly according to any of aspects 1-4, wherein the substrate container includes a shell defining an internal space and a bottom plate.

Aspect 6. The assembly according to aspect 5, wherein the aperture is formed in the shell.

Aspect 7. The assembly according to any of aspects 5-6, wherein the aperture is formed in both the shell and the bottom plate.

Aspect 8. The assembly according to aspect 7, wherein the one or more tabs are provided on the bottom plate.

Aspect 9. The assembly according to any of aspects 1-8, wherein the module retainer includes one or more tooling interfaces on an outward-facing surface of the module retainer.

Aspect 10. The assembly according to aspect 9, wherein the tooling interfaces are distributed around a central opening formed in the outward-facing surface of the module retainer. Aspect 11. A method of installing a module into a substrate container, comprising:
inserting a module including a module retainer into an aperture formed in the substrate container, wherein the module retainer is in a first position where engagement features of the module retainer can pass through gaps between tabs extending inwards into the aperture; and
rotating the module retainer into a second position where the engagement features of the module retainer engage with the tabs.

Aspect 12. The method according to aspect 11, wherein the module is selected from the group consisting of: a vent module, a purge module, a getter module, a sensor module, and an interface module.

Aspect 13. The method according to any of aspects 11-12, further comprising attaching the module retainer to the module.

Aspect 14. The method according to aspect 13, wherein attaching the module retainer to the module includes forming a snap-fit between at least one first snap-fit feature provided on the module retainer and at least one second snap-fit feature provided on a body of the module.

Aspect 15. The method according to any of aspects 11-14, wherein the aperture is formed in a shell of the substrate container.

Aspect 16. The method according to any of aspects 11-14, wherein the aperture is formed in a shell and a bottom plate of the substrate container, and the tabs are provided on the bottom plate.

Aspect 17. The method according to any of aspects 11-16, wherein rotating the module retainer includes inserting a tool into one or more tooling interfaces provided in the module retainer.

Aspect 18. The method of according to aspect 17, wherein the tool is manipulated by automation.

Aspect 19. The method according to any of aspects 11-18, further comprising rotating the module retainer from the second position to the first position and removing the module from the aperture.

Aspect 20. The method according to any of aspects 11-19, wherein when the module is installed in the aperture and the module retainer is in the second position, the aperture is sealed.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. An assembly comprising a substrate container, the substrate container including:
an aperture formed in the substrate container, the aperture configured to receive a module;
one or more tabs, each of the one or more tabs extending inwards into the aperture over a portion of a perimeter of the aperture, the one or more tabs defining one or more gaps;
a module; and
a module retainer attached to the module, the module retainer including one or more of engagement features, wherein the engagement features are configured to be inserted through a corresponding one or more of gaps when in a first position and to engage with the one or more tabs when in a second position, the module retainer configured to be rotatable between the first position and the second position when the module retainer is inserted into the aperture.

2. The assembly of claim 1, wherein the module retainer includes a detent configured to contact one of the one or more gaps so as to resist rotation of the module retainer from the second position to the first position.

3. The assembly of claim 1, wherein the module is selected from the group consisting of: a purge module, a vent purge module, a getter module, and a sensor module.

4. The assembly of claim 1, wherein the one or more tabs include at least three tabs, and the one or more engagement features includes at least three engagement features.

5. The assembly of claim 1, wherein the substrate container includes a shell defining an internal space and a bottom plate.

6. The assembly of claim 5, wherein the aperture is formed in the shell.

7. The assembly of claim 5, wherein the aperture is formed in both the shell and the bottom plate.

8. The assembly of claim 7, wherein the one or more tabs are provided on the bottom plate.

9. The assembly of claim 1, wherein the module retainer includes one or more tooling interfaces on an outward-facing surface of the module retainer.

10. The assembly of claim 9, wherein the tooling interfaces are distributed around a central opening formed in the outward-facing surface of the module retainer.

11. A method of installing a module into a substrate container, comprising:
inserting a module including a module retainer into an aperture formed in the substrate container, wherein the module retainer is in a first position where engagement features of the module retainer can pass through gaps between tabs extending inwards into the aperture; and
rotating the module retainer into a second position where the engagement features of the module retainer engage with the tabs.

12. The method of claim 11, wherein the module is selected from the group consisting of: a vent module, a purge module, a getter module, a sensor module, and an interface module.

13. The method of claim 11, further comprising attaching the module retainer to the module.

14. The method of claim 13, wherein attaching the module retainer to the module includes forming a snap-fit between at least one first snap-fit feature provided on the module retainer and at least one second snap-fit feature provided on a body of the module.

15. The method of claim 11, wherein the aperture is formed in a shell of the substrate container.

16. The method of claim 11, wherein the aperture is formed in a shell and a bottom plate of the substrate container, and the tabs are provided on the bottom plate.

17. The method of claim 11, wherein rotating the module retainer includes inserting a tool into one or more tooling interfaces provided in the module retainer.

18. The method of claim 17, wherein the tool is manipulated by automation.

19. The method of claim 11, further comprising rotating the module retainer from the second position to the first position and removing the module from the aperture.

20. The method of claim 11, wherein when the module is installed in the aperture and the module retainer is in the second position, the aperture is scaled.
